(19) United States
(12) Patent Application Publication
(10) Pub. No.: US 2007/0122920 A1
(43) Pub. Date: May 31, 2007

(54) Method for improved control of critical dimensions of etched structures on semiconductor wafers

(76) Inventors: William B. Bornstein, Hopewell Junction, NY (US); Anthony Cappa Spielberg, Austin, TX (US)

Correspondence Address: DUKE W. YEE;YEE & ASSOCIATES, P.C., P.O. BOX 802333, DALLAS, TX, 75380, US

(21) Appl. No.: 11/289,074

(22) Filed: Nov. 29, 2005

(51) Int. Cl. H01L 21/00; G06F 19/00; C23F 1/00; H01L 21/302

(52) U.S. Cl. 438/5; 438/689; 700/121; 156/345.25

(57) ABSTRACT

A system for real-time monitoring and control of critical dimensions during semiconductor wafer fabrication is provided. The system measures structures in situ, that is, as they are being etched onto a wafer layer.

### BACKGROUND OF THE INVENTION

1. Field of the Invention

The present invention relates to a method and system for monitoring and controlling processing carried out on a semiconductor substrate, and more particularly for controlling critical dimensions (CDs) of features formed on the semiconductor substrate.

2. Description of the Related Art

In the integrated circuit industry today, millions of semiconductor devices are built on a single chip. The current demands for high density and performance associated with ultra large scale integration require submicron features, increased transistor and circuit speeds and improved reliability. Every device on the chip must be electrically isolated to ensure that it operates independently without interfering with another.

Such demands require formation of device features with high precision and uniformity, which in turn necessitates careful process monitoring, including frequent and detailed inspections of the devices while they are still in the form of semiconductor wafers.

One important process requiring careful inspection is photolithography, wherein masks are used to transfer circuitry patterns to semiconductor wafers. Typically, a series of such masks are employed in a preset sequence. Each photolithographic mask includes an intricate set of geometric patterns corresponding to the circuit components to be integrated onto the wafer. Each mask in the series is used to transfer its corresponding pattern onto a photosensitive layer (i.e., a photoresist layer) which has been previously coated on a layer, such as a polysilicon or metal layer, formed on the silicon wafer. The transfer of the mask pattern onto the photoresist layer is conventionally performed by an optical exposure tool such as a scanner or a stepper, which directs light or other radiation through the mask to expose the photoresist. The photoresist is thereafter developed to form a photoresist mask, and the underlying polysilicon or metal layer is selectively etched in accordance with the mask to form features such as lines or gates. In between some polysilicon layers and metal layers are other layers called insulating layers.

Fabrication of the mask follows a set of predetermined design rules set by processing and design limitations. These design rules define the space tolerance between devices and interconnecting lines and the width of the lines themselves, to ensure that the devices or lines do not overlap or interact with one another in undesirable ways. For modern semiconductor fabrication technologies, dimensions of structures fabricated at the wafer level are often small fractions of a micron.

As design rules shrink and process windows (i.e., the margins for error in processing) become smaller, inspection and measurement of surface features becomes more important. Some features have especially important effects on final product function, performance, or reliability, and so their dimensions must be carefully controlled. Such features are commonly referred to as “critical dimensions” or CDs. CDs, as well as their cross-sectional shape (“profile”) are becoming increasingly important. Deviations of a feature's CD and profile from design dimensions may adversely affect the performance of the finished semiconductor device. Furthermore, the measurement of a feature's CD and profile may indicate processing problems, such as stepper defocusing or photoresist loss due to over-exposure.

Thus, CD and profile values, and the variation of feature CD from design dimensions, are important indicators of the accuracy and stability of the photoresist and etch processes, and “CD control” to reduce such variation is an important part of semiconductor processing. CD control necessarily involves monitoring and adjusting both the photolithography and etch processes to address CD variations, both from field to field across a wafer, and within-field.

Because of the extremely small scale of current CD's, the instrument of choice for measurement and inspection of surface features produced by photolithographic processing is a scanning electron microscope (SEM) known as a “critical dimension scanning electron microscope” (CD-SEM). Although conventional SEM's are useful for measuring CD's, they generally do not provide immediate feedback to the photolithography process. SEM measurement is performed “off-line” because it is relatively slow and typically needs to be performed at a separate review station. Consequently, the results of conventional SEM inspections are not typically used to adjust subsequent etch processing; that is, the CD measurement of a particular wafer is not used to decide what etch recipe should be used to process that wafer.

Thus, the information gathered from the CD-SEM measurement is not utilized to the fullest extent that will help to improve yield. As a further consequence of the inspection necessarily taking place at a physically separate tool, the wafers must be transferred to and from the tool for every inspection performed, which is inefficient.

Another technique is called Adaptive Process Control (APC). APC uses feedback or feed-forward loops to tune etch operations on a lot-by-lot or wafer-by-wafer basis, by using information from other operations such as, for example, the thickness of film to be etched. While APC is better than having no feedback, it still offers only the chance to make one educated guess as to how to best adjust the etch recipe to correct for CD variations.

Therefore, it would be advantageous to have an improved method and system capable of real-time, fast, accurate and meaningful control and prevention of CD variation without significantly reducing production throughput or yield.

### SUMMARY OF THE INVENTION

The present invention provides a method, system and computer program product for real-time monitoring and control of critical dimensions during semiconductor wafer fabrication. The method, system, and computer program product measures structures in situ, that is, as they are being etched onto a wafer layer.

### BRIEF DESCRIPTION OF THE DRAWINGS

The novel features believed characteristic of the invention are set forth in the appended claims. The invention itself, however, as well as a exemplary mode of use, further objectives and advantages thereof, will best be understood by reference to the following detailed description of an illustrative embodiment when read in conjunction with the accompanying drawings, wherein:

FIG. 1 is a block diagram of a system in which the present invention may be implemented according to an exemplary embodiment of the present invention;

FIG. 2 is a flowchart that illustrates a method for checking critical dimensions in accordance with an exemplary embodiment of the present invention;

FIG. 3 is an illustrative diagram of a cross-section through a region of a silicon wafer in the course of being fabricated into an integrated circuit;

FIG. 4 is a pictorial representation of a network of data processing systems in which exemplary aspects of the present invention may be implemented; and

FIG. 5 is a block diagram of a data processing system in which exemplary aspects of the present invention may be implemented.

### DETAILED DESCRIPTION OF THE PREFERRED EMBODIMENT

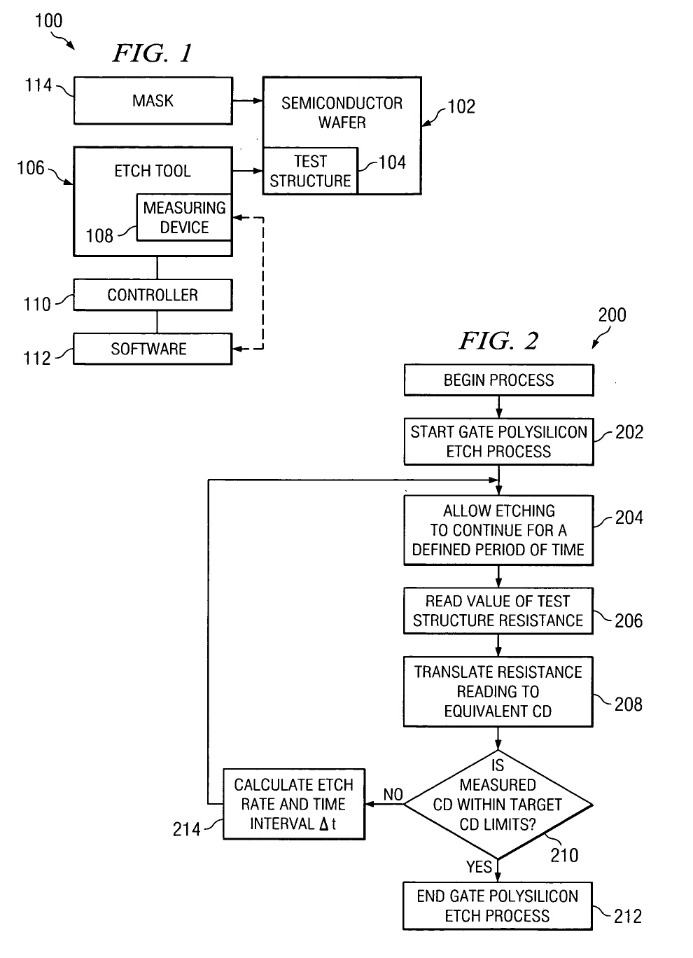

With reference now to the figures and in particular with reference to FIG. 1, a block diagram of a system in which the present invention may be implemented is depicted according to an exemplary embodiment of the present invention. The system is designated by reference number 100. Semiconductor wafer 102 is depicted, onto which test structure 104 is etched. In order to etch test structure 104 onto semiconductor wafer 102, etch tool 106 and mask 114 is used. Measuring device 108 is part of etch tool 106 and is capable of measuring the CDs of test structure 104.

As test structure 104 is being etched on the semiconductor wafer 102, measuring device 108 provides real-time, in situ measurement and feed back of the process. Measuring device 108 may be many different types of devices, including, but not limited to, a scanning electron microscope, a mechanical probe making direct electrical contact with etched structures, or a device with image recognition software capable of analyzing a magnetic field induced by magnetically exciting the etched structures. In an exemplary embodiment, measuring device 108 measures eddy-currents in test structure 104.

One form of magnetic imaging technique is nuclear magnetic resonance (NMR), which is similar to magnetic resonance imaging (MRI). Both are non-destructive and non-invasive analysis tools. Another possible imaging technique is magnetic force microscopy (MFM). MFM is used for imaging magnetic field gradient and its distribution above the sample surface. MFM is capable of imaging magnetic domains of several tens of nanometers.

Controller 110 controls etch tool 106 and measuring device 108. Software 112 performs many functions including capturing and recording measurements from measuring device 108, translating the captured data into CD values for test structure 104, comparing the measured CD values to the desired CD values for test structure 104 and stopping the etch process when the measured CD value is within the acceptable target limits for test structure 104.

In an exemplary embodiment, controller 110 and software 112 are part of etch tool 106. Measuring device 108 measures critical dimensions, in the x and/or y directions, of test structure 104 as it is being etched on semiconductor wafer 102, through use of software 112. Once software 112 determines that the measured critical x and/or y dimensions of test structure 104 are within the acceptable target limits, controller 110 stops etch tool 106 from further etching of semiconductor wafer 102.

While the above process has been described in terms of having controller 110 and software 112 as part of etch tool 106, those skilled in the art will appreciate that several alternate embodiments of controller 110 and software 112 exist, depending upon the implementation. For instance, software 112 could actually consist of several different application programs resident in a single location or multiple locations. Software 112 may reside entirely on etch tool 106, within measuring device 108 or it may be completely separate from those devices. Software 112 could exist partly on etch tool 106 and/or measuring device 108 and partly at another location, such as controller 110. Software 112 could reside entirely on controller 110. Similarly, controller 110 may be part of etch tool 106 or measuring device 108 or it may be entirely separate from those devices. Controller 110 could consist of multiple devices, each of which controls some specific tool or aspect of the process.

In one exemplary embodiment, controller 110 stops the etching process once it has been determined that the measured CD value is within an acceptable target limit by communicating directly with etch tool 106, telling etch tool 106 to stop etching. In another embodiment, controller 110 sends a signal to the controller of etch tool 106 stating that the measured CD value is within an acceptable target limit and controller 110 then tells etch tool 106 to stop etching.

It should be understood the system illustrated in FIG. 1 is exemplary only and may be modified in various ways depending on particular implementations.

Referring to FIG. 2, a flowchart that illustrates a method for checking critical dimensions in accordance with an exemplary embodiment of the present invention is shown. The method of FIG. 2 may be implemented on a semiconductor wafer, such as semiconductor wafer 102 in FIG. 1.

The method is designated by reference number 200 and makes use of APC, where the results of a given manufacturing operation are used to adjust the targets for a subsequent operation, in order to achieve improved control of the results of the integrated process. Method 200 begins by starting a gate polysilicon etch process (step 202). Etching is allowed to continue for a defined period of time Δt (step 204). A measuring device, such as measuring device 108 in FIG. 1, begins taking in situ measurements of the critical x and/or y dimensions of the test structure being etched. This is done by reading the value of the test structure's resistance (step 206). Software, such as software 112 in FIG. 1, translates the resistance reading to an equivalent CD value (step 208). A determination is made as to whether or not the measured CD value is within an acceptable target limit for the target CD value (step 210). If the measured CD value is within an acceptable target limit for the target CD value (a yes output to step 210), then the gate silicon etch process is stopped (step 212). If the measured CD value is not within an acceptable target limit for the target CD value (a no output to step 210), then the etch rate and time interval Δt necessary to reach the target CD is calculated (step 214) and step 204 is repeated.

It should be understood the process illustrated in FIG. 2 is exemplary only and may be modified in various ways depending on particular implementations. For example, the measuring device might be capable of stopping the etching process itself by directly sending the stop command, or it may send a signal to another device, which then stops the etching.

It is important to note that while the above described process has been described in terms of an implementation for conducting layers, the process is equally applicable to insulating layers and can be implemented for such. For example, in situ measurements could be made of CDs for contact opening or via openings in dielectric layers. The above described process also applies to the creation of lithographic masks.

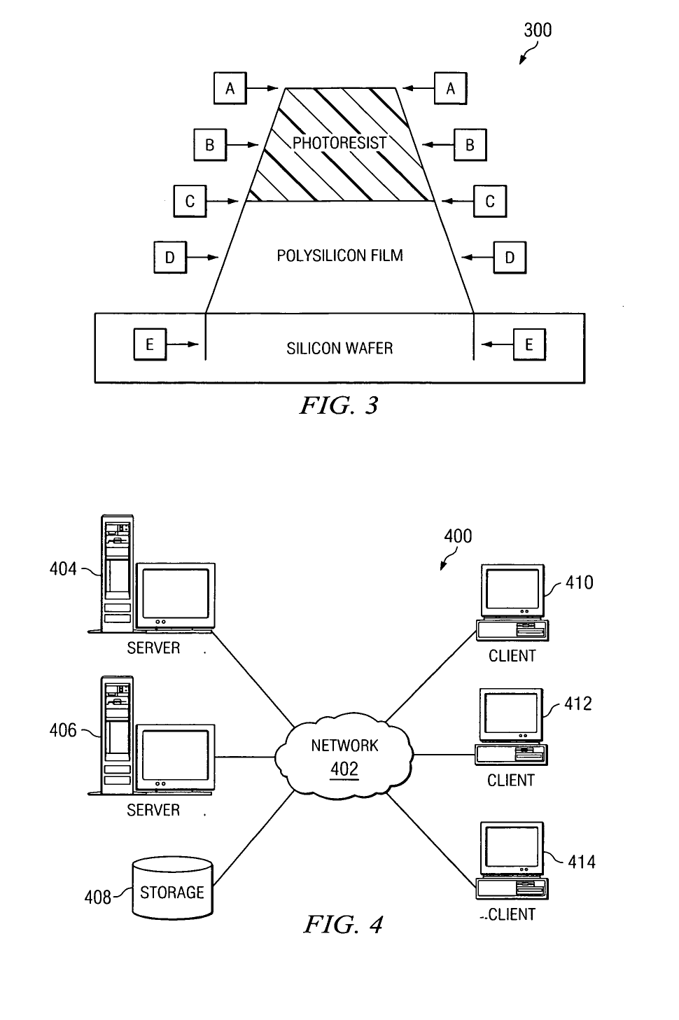

FIG. 3 is an illustrative diagram of a cross-section through a region of a silicon wafer in the course of being fabricated into an integrated circuit. The cross-section is designated by reference number 300 and is not drawn to scale. Cross-section 300 is taken after gate polysilicon photolithography and etching have been completed, and prior to the removal of the photoresist mask used during gate polysilicon etching.

“A” is the CD of the photoresist, as measured at the top of its film thickness. “B” is the CD of the photoresist as measured mid-way through its film thickness. “C” is the CD of the photoresist as measured at the bottom of its film thickness, which corresponds to the CD of the gate polysilicon pattern at the top of its film thickness. “D” is the CD of the gate polysilicon line mid-way through its film thickness. “E” is the CD of the polysilicon pattern at the bottom of its film thickness.

Depending on what the CD measurement will be used for, one or another of the CDs associated with a given structure will be of most interest and utility in the manufacturing sequence.

In an exemplary embodiment of the present invention, the CDs of interest would be C, D, and E. Depending on which method is used to make the in-situ measurements of the test structure, one or more of these CDs would be measured. In fact, if an appropriate choice of method is made (e.g., SEM,) the CD of the polysilicon line could be measured at any point in its film thickness, not only the three points used as examples in this diagram.

Thus the present invention solves the disadvantages of the prior art by providing in situ measurement and control of critical x and y dimensions during the semiconductor wafer fabrication process. The present invention provides a method, system and computer program product for real-time monitoring and control of critical dimensions during wafer fabrication. The method, system, and computer program product monitors circuit patterns in situ, that is, as they are being etched onto a wafer layer, in order to provide more precise control over critical x and/or y dimensions of the pattern. As a polysilicon or metal layer is being etched, a measuring device, such as a scanning electron microscope or image recognition software, monitors the pattern as it is being formed and provides immediate feedback. Once the measuring device determines that the pattern is within an acceptable target limit of its proper x and/or y critical dimensions, the measuring device signals for the etching process to stop. In this manner, adherence to critical dimensions during the production of semiconductor wafers is greatly increased without reducing production yield or throughput.

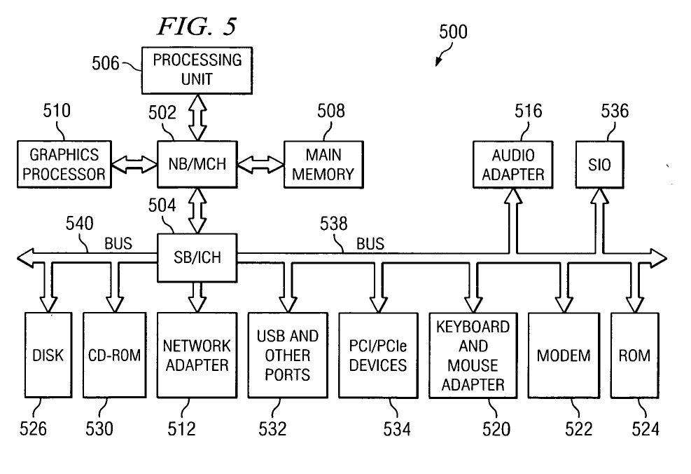

FIGS. 4-5 are provided as exemplary diagrams of data processing environments in which embodiments of the present invention may be implemented. It should be appreciated that FIGS. 4-5 are only exemplary and are not intended to assert or imply any limitation with regard to the environments in which aspects or embodiments of the present invention may be implemented. Many modifications to the depicted environments may be made without departing from the spirit and scope of the present invention.

With reference now to the figures, FIG. 4 depicts a pictorial representation of a network of data processing systems in which aspects of the present invention may be implemented. Network data processing system 400 is a network of computers in which embodiments of the present invention may be implemented. Network data processing system 400 contains network 402, which is the medium used to provide communications links between various devices and computers connected together within network data processing system 400. Network 402 may include connections, such as wire, wireless communication links, or fiber optic cables.

In the depicted example, server 404 and server 406 connect to network 402 along with storage unit 408. In addition, clients 410, 412, and 414 connect to network 402. These clients 410, 412, and 414 may be, for example, personal computers or network computers. In the depicted example, server 404 provides data, such as boot files, operating system images, and applications to clients 410, 412, and 414. Clients 410, 412, and 414 are clients to server 404 in this example. Network data processing system 400 may include additional servers, clients, and other devices not shown.

In the depicted example, network data processing system 400 is the Internet with network 402 representing a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers, consisting of thousands of commercial, government, educational and other computer systems that route data and messages. Of course, network data processing system 400 also may be implemented as a number of different types of networks, such as for example, an intranet, a local area network (LAN), or a wide area network (WAN). FIG. 4 is intended as an example, and not as an architectural limitation for different embodiments of the present invention.

With reference now to FIG. 5, a block diagram of a data processing system is shown in which aspects of the present invention may be implemented. Data processing system 500 is an example of a computer, such as server 404 or client 410 in FIG. 4, in which computer usable code or instructions implementing the processes for embodiments of the present invention may be located.

In the depicted example, data processing system 500 employs a hub architecture including north bridge and memory controller hub (MCH) 502 and south bridge and input/output (I/O) controller hub (ICH) 504. Processing unit 506, main memory 508, and graphics processor 510 are connected to north bridge and memory controller hub 502. Graphics processor 510 may be connected to north bridge and memory controller hub 502 through an accelerated graphics port (AGP).

In the depicted example, LAN adapter 512 connects to south bridge and I/O controller hub 504. Audio adapter 516, keyboard and mouse adapter 520, modem 522, read only memory (ROM) 524, hard disk drive (HDD) 526, CD-ROM drive 530, universal serial bus (USB) ports and other communications ports 532, and PCI/PCIe devices 534 connect to south bridge and I/O controller hub 504 through bus 538 and bus 540. PCI/PCIe devices may include, for example, Ethernet adapters, add-in cards and PC cards for notebook computers. PCI uses a card bus controller, while PCIe does not. ROM 524 may be, for example, a flash binary input/output system (BIOS).

Hard disk drive 526 and CD-ROM drive 530 connect to south bridge and I/O controller hub 504 through bus 540. Hard disk drive 526 and CD-ROM drive 530 may use, for example, an integrated drive electronics (IDE) or serial advanced technology attachment (SATA) interface. Super I/O (SIO) device 536 may be connected to south bridge and I/O controller hub 504.

An operating system runs on processing unit 506 and coordinates and provides control of various components within data processing system 500 in FIG. 5. As a client, the operating system may be a commercially available operating system such as Microsoft® Windows® XP (Microsoft and Windows are trademarks of Microsoft Corporation in the United States, other countries, or both). An object-oriented programming system, such as the Java™ programming system, may run in conjunction with the operating system and provides calls to the operating system from Java programs or applications executing on data processing system 200 (Java is a trademark of Sun Microsystems, Inc. in the United States, other countries, or both).

As a server, data processing system 500 may be, for example, an IBM eServer™ pSeries® computer system, running the Advanced Interactive Executive (AIX®) operating system or LINUX operating system (eServer, pSeries and AIX are trademarks of International Business Machines Corporation in the United States, other countries, or both while Linux is a trademark of Linus Torvalds in the United States, other countries, or both). Data processing system 500 may be a symmetric multiprocessor (SMP) system including a plurality of processors in processing unit 506. Alternatively, a single processor system may be employed.

Instructions for the operating system, the object-oriented programming system, and applications or programs are located on storage devices, such as hard disk drive 526, and may be loaded into main memory 508 for execution by processing unit 506. The processes for embodiments of the present invention are performed by processing unit 506 using computer usable program code, which may be located in a memory such as, for example, main memory 508, read only memory 524, or in one or more peripheral devices 526 and 530.

Those of ordinary skill in the art will appreciate that the hardware in FIGS. 4-5 may vary depending on the implementation. Other internal hardware or peripheral devices, such as flash memory, equivalent non-volatile memory, or optical disk drives and the like, may be used in addition to or in place of the hardware depicted in FIGS. 4-5. Also, the processes of the present invention may be applied to a multiprocessor data processing system.

In some illustrative examples, data processing system 500 may be a personal digital assistant (PDA), which is configured with flash memory to provide non-volatile memory for storing operating system files and/or user-generated data.

A bus system may be comprised of one or more buses, such as bus 538 or bus 540 as shown in FIG. 5. Of course the bus system may be implemented using any type of communications fabric or architecture that provides for a transfer of data between different components or devices attached to the fabric or architecture. A communications unit may include one or more devices used to transmit and receive data, such as modem 522 or network adapter 512 of FIG. 5. A memory may be, for example, main memory 508, read only memory 524, or a cache such as found in north bridge and memory controller hub 502 in FIG. 5. The depicted examples in FIGS. 4-5 and above-described examples are not meant to imply architectural limitations. For example, data processing system 500 also may be a tablet computer, laptop computer, or telephone device in addition to taking the form of a PDA.

The invention can take the form of an entirely hardware embodiment or an embodiment containing both hardware and software elements. In an exemplary embodiment, aspects of the invention are implemented in software, which includes but is not limited to firmware, resident software, microcode, etc.

Furthermore, the invention can take the form of a computer program product accessible from a computer-usable or computer-readable medium providing program code for use by or in connection with a computer or any instruction execution system. For the purposes of this description, a computer-usable or computer readable medium can be any tangible apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

What is claimed is:

1. A method in a semiconductor wafer fabrication system for real-time monitoring of critical dimensions of structures, the method comprising:
measuring critical dimensions of a structure as the structure is being etched.

2. The method of claim 1, further comprising:
responsive to a determination that a measured critical dimension is within a target limit, stopping etching of the structure.

3. The method of claim 1, further comprising:
applying adaptive process control to control critical dimensions.

4. The method of claim 1, wherein the measuring step comprises at least one of measuring the critical dimensions with a scanning electron microscope, using magnetic excitation to induce eddy currents and then analyzing a resulting magnetic field, or measuring the critical dimension with a mechanical probe that makes direct electrical contact with the structure.

5. The method of claim 4, wherein analyzing a resulting magnetic field comprises analyzing the resulting magnetic field using image recognition software.

6. The method of claim 1, wherein the structure comprises a structure etched on a semiconductor wafer layer.

7. The method of claim 6, wherein the semiconductor wafer layer comprises at least one of a conducting layer, an insulating layer or a semiconducting layer.

8. The method of claim 1, wherein the structure comprises a structure etched on a lithographic mask.

9. A computer program product comprising a computer usable medium including computer usable program code for real-time monitoring of critical dimensions of structures in a semiconductor wafer fabrication system, said computer program product including:
computer usable program code for measuring critical dimensions of a structure as the structure is being etched.

10. The computer program product of claim 9, further comprising:
computer usable program code, responsive to a determination that a measured critical dimension is within a target limit, for stopping etching of the structure.

11. The computer program product of claim 9, further comprising:
computer usable program code for applying adaptive process control to control critical dimensions.

12. The computer program product of claim 9, wherein the computer usable program code for measuring critical dimensions of a structure as the structure is being etched comprises at least one of computer usable program code for measuring the critical dimensions with a scanning electron microscope, computer usable program code for using magnetic excitation to induce eddy currents and then analyzing a resulting magnetic field, or computer usable program code for measuring the critical dimension with a mechanical probe that makes direct electrical contact with the structure.

13. A semiconductor wafer fabrication system for real-time monitoring of critical dimensions of a structure, comprising:
measuring mechanism for measuring critical dimensions of a structure as the structure is etched.

14. The semiconductor wafer fabrication system of claim 13 further comprising:
stopping mechanism, responsive to a determination that a measured critical dimension is within a target limit, for stopping etching of the structure.

15. The semiconductor wafer fabrication system of claim 13, further comprising:
controlling mechanism for applying adaptive process control to control critical dimensions.

16. The semiconductor wafer fabrication system of claim 13, wherein the measuring mechanism comprises at least one of a scanning electron microscope, a mechanical probe that makes direct electrical contact with the structure, or a mechanism for using magnetic excitation to induce eddy currents and then analyzing a resulting magnetic field.

17. The semiconductor wafer fabrication system of claim 16, wherein analyzing a resulting magnetic field comprises analyzing the resulting magnetic field utilizing image recognition software.

18. The semiconductor wafer fabrication system of claim 13, wherein the structure comprises a structure etched on a semiconductor wafer layer.

19. The semiconductor wafer fabrication system of claim 18, wherein the semiconductor wafer layer comprises at least one of a conducting layer, an insulating layer or a semiconducting layer.

20. The semiconductor wafer fabrication system of claim 13, wherein the structure comprises a structure etched on a lithographic mask.
